(19) United States
(12) Patent Application Publication
(10) Pub. No.: US 2026/0165372 A1
(43) Pub. Date: Jun. 18, 2026

(54) AEROSOL GENERATING DEVICE

(71) Applicant: KT&G CORPORATION, Daejeon (KR)

(72) Inventors: Dongsung KIM, Daejeon (KR); Youngbum KWON, Daejeon (KR); Yonghwan KIM, Daejeon (KR); Hwikyeong AN, Daejeon (KR)

(73) Assignee: KT&G CORPORATION, Daejeon (KR)

(21) Appl. No.: 19/335,180

(22) Filed: Sep. 22, 2025

(30) Foreign Application Priority Data
Dec. 17, 2024 (KR) 10-2024-0188870

(51) Int. Cl. A24F 40/40; F16C 27/02

(52) U.S. Cl. CPC A24F 40/40; F16C 27/02

(57) ABSTRACT

An aerosol generating device includes a housing comprising an opening into which an aerosol generating article is insertable, a door configured to be movable relative to the housing to open and close the opening, and a bearing positioned between the door and the housing and configured to rotate to movably support the door relative to the housing.

### CROSS-REFERENCE TO RELATED APPLICATION

This application is based on and claims priority under 35 U.S.C. § 119 to Korean Patent Application No. 10-2024-0188870, filed on Dec. 17, 2024, in the Korean Intellectual Property Office, the disclosure of which is incorporated by reference herein in its entirety.

### BACKGROUND

### 1. Field

Embodiments relate to an aerosol generating device, and more particularly, to an aerosol generating device including a door having improved durability and smooth operation.

### 2. Description of the Related Art

Recently, there has been an increasing demand for an alternative method of overcoming the disadvantages of normal cigarettes. For example, there is an increasing demand for a system for generating aerosols by heating an aerosol generating substrate by using an aerosol generating device, rather than by burning cigarettes.

The door of an aerosol generating device may close or open a space in which an aerosol generating article is accommodated. Also, the door may block external foreign materials from entering the aerosol generating device and when the aerosol generating device is in use, the door may open the space in which the aerosol generating article is accommodated.

### SUMMARY

Because a door is movably installed relative to a housing of an aerosol generating device, it is preferable to reduce mechanical friction between the door and the housing and interference between components to ensure a smooth operation of the door. As the door is repeatedly used, some components of the aerosol generating device related to the operation of the door may wear or break. In such a case, the door may not smoothly operate or may become inoperable.

Embodiments provide an aerosol generating device including a door that smoothly operates.

Furthermore, embodiments provide an aerosol generating device including a door that reduces wear or breakage of components related to the operation of the door.

Technical goals to be achieved through embodiments are not limited thereto, and technical goals unmentioned above would be clearly understood to those skilled in the art based on the present specification and the accompanying drawings.

Additional aspects will be set forth in part in the description which follows and, in part, will be apparent from the description, or may be learned by practice of the presented embodiments of the disclosure.

An aerosol generating device according to an aspect includes a housing comprising an opening into which an aerosol generating article is insertable, a door configured to be movable relative to the housing to open and close the opening; and a bearing positioned between the door and the housing and configured to rotate to support the door movably relative to the housing.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an aerosol generating device according to an embodiment;

FIG. 2 illustrates an aerosol generating device according to another embodiment;

FIG. 3 illustrates an aerosol generating device according to another embodiment;

FIG. 4 is a perspective view of the aerosol generating device according to the embodiment illustrated in FIG. 3;

FIG. 5 is a perspective view schematically illustrating a portion of an aerosol generating device according to another embodiment;

FIG. 6 is an exploded perspective view illustrating elements of a door assembly of the aerosol generating device according to the embodiment illustrated in FIG. 5;

FIG. 7 is a longitudinal cross-sectional view of a portion of the aerosol generating device according to the embodiment illustrated in FIG. 5;

FIG. 8 is a longitudinal cross-sectional view illustrating another operating state of a door of the aerosol generating device illustrated in FIG. 7;

FIG. 9 is a transverse cross-sectional view of a portion of the aerosol generating device illustrated in FIG. 7;

FIG. 10 is a transverse cross-sectional view of a portion of the aerosol generating device illustrated in FIG. 8;

FIG. 11 is a cross-sectional view schematically illustrating a portion of an aerosol generating device according to another embodiment;

FIG. 12 is a cross-sectional view schematically illustrating a portion of an aerosol generating device according to another embodiment;

FIG. 13 is a cross-sectional view schematically illustrating a portion of an aerosol generating device according to another embodiment;

FIG. 14 is a perspective view schematically illustrating a portion of an aerosol generating device according to another embodiment; and

FIG. 15 is a perspective view schematically illustrating a portion of an aerosol generating device according to another embodiment.

### DETAILED DESCRIPTION

Hereinafter, embodiments will be described in detail with reference to the accompanying drawings, and the same or similar components will be assigned the same reference numerals regardless of the reference numerals in the drawings, and the same descriptions thereof will be omitted. With regard to the description of the drawings, like reference numerals may be used to represent like or related elements.

The suffixes “module”, “-er”, and “-or” for the components used in the following description are given or used interchangeably by considering only the ease of writing the description, and do not have distinct meanings or roles in themselves. The suffix “module” or “unit”, as used herein, may include a unit implemented as hardware, software, or firmware. For example, the suffix “module” or “unit” may be interchangeably used with the term a “logic”, a “logical block”, a “component”, or a “circuit”. The “module” or “unit” may be an integrally formed component, a minimum unit of the component performing one or more functions, or a part of the minimum unit. For example, the “module” or “unit” may be implemented in the form of an application-specific integrated circuit (ASIC).

In addition, when describing the embodiments of the disclosure, the detailed description of the related known art, which may obscure the subject matter of the embodiments, may be omitted. Also, the accompanying drawings are only intended to facilitate understanding of the embodiments described herein, and the spirit of the disclosure is not limited by the accompanying drawings and should be understood to include all changes, equivalents or alternatives included in the spirit and scope of the disclosure.

Although the terms first, second, etc. may be used herein to describe various elements or components, these elements or components should not be limited by these terms. These terms are only used to distinguish one element or component from another element or component.

When an element is referred to as being “connected to” or “coupled to” another element, it may be directly connected or coupled to the other element or intervening elements may be present. In contrast, when an element is referred to as being “directly connected to” or “directly coupled to” another element, there are no intervening elements present.

The singular forms are intended to include the plural forms as well, unless the context clearly indicates otherwise.

Various embodiments of the present disclosure may be implemented as software including one or more instructions stored in a storage medium (e.g., a memory 17) readable by a machine (e.g., an aerosol generating device 1). For example, a processor (e.g., a controller 12) of the machine (e.g., the aerosol generating device 1) may call at least one instruction among one or more instructions stored from the storage medium and execute the at least one instruction. This makes it possible for the machine to be operated to perform at least one function according to the called at least one instruction. Examples of the one or more instructions may include codes created by a compiler, or codes executable by an interpreter. A machine-readable storage medium may be provided as a non-transitory storage medium. The ‘non-transitory storage medium’ is a tangible device and only means that it does not contain a signal (e.g., electromagnetic waves). This term does not distinguish a case in which data is stored semi-permanently in a storage medium from a case in which data is temporarily stored.

In the present disclosure, a direction of the aerosol generating device 1 may be defined based on an orthogonal coordinate system. The X-axis direction in the orthogonal coordinate system may be defined as a left-right direction of the aerosol generating device 1. The Y-axis direction may be defined as a front-back direction of the aerosol generating device 1. The Z-axis direction may be defined as an upward and downward direction of the aerosol generating device 1.

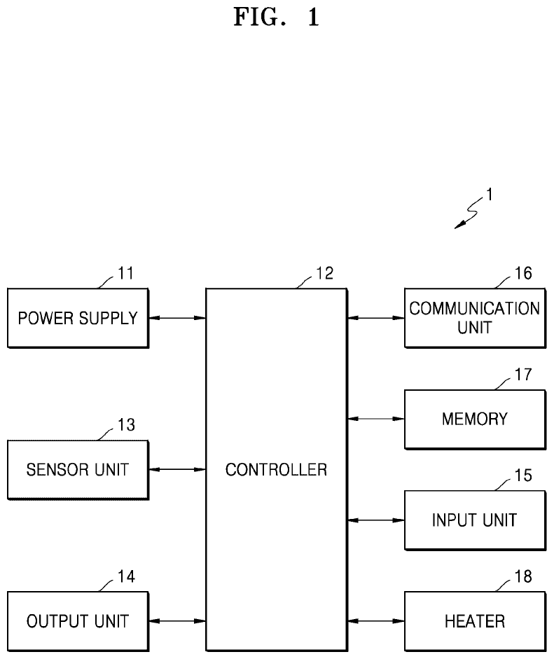

FIG. 1 is a block diagram of the aerosol generating device 1 according to an embodiment.

According to an embodiment, the aerosol generating device 1 may include a power supply 11, the controller 12, a sensor unit 13, an output unit 14, an input unit 15, a communication unit 16, a memory 17, and/or heater 18. However, it may be understood by those skilled in the art that some of the components shown in FIG. 1 may be omitted or new components may be added, according to the design of the aerosol generating device 1.

According to an embodiment, the sensor unit 13 may sense a state of the aerosol generating device 1 or a state of the surroundings of the aerosol generating device 1 and may transmit information corresponding to the sensed state to the controller 12. For example, the sensor unit 13 may include a temperature sensor, a puff sensor, an insertion detection sensor, a reuse detection sensor, an overwetting detection sensor, a cigarette identification sensor, a cartridge detection sensor, a cap detection sensor, and/or a movement detection sensor. The sensor unit 13 may further include various sensors, such as a liquid remaining amount sensor for detecting the liquid remaining amount of a cartridge and an immersion sensor for detecting immersion of the aerosol generating device 1.

According to an embodiment, the temperature sensor may detect the heating temperature of the heater 18 The aerosol generating device 1 may include a separate temperature sensor for detecting respective temperatures of the heater 18, or the heater 18 may serve as a temperature sensor. For example, the temperature sensor may be used to measure an impedance of the heater 18. The impedance of the heater 18 may be correlated with the temperature of the heater 18. The temperature sensor may measure a current and/or voltage applied to the heater 18 (or an induction coil). Based on the measured current and/or voltage, the impedance for the heater 18 may be calculated. The controller 12 may estimate the temperature of the heater 18, based on the calculated impedance.

For example, the temperature sensor may include a resistive element (e.g., a thermistor) whose resistance value changes in response to a change in temperatures of the heater 18. The temperature sensor may output a signal corresponding to the resistance value of the resistive element, and the controller 12 may detect the temperatures and/or temperature changes of the heater 18, based on the signal corresponding to the resistance value.

As another example, the temperature sensor may include a sensor for detecting the resistance values of the heater 18. The temperature sensor may output signals corresponding to the resistance values of the heater 18, and the controller 12 may detect the temperatures and/or temperature changes of the heater 18, based on the signals corresponding to the resistance values.

According to an embodiment, the temperature sensor may detect a temperature of the power supply 11. The temperature sensor may be disposed adjacent to the power supply 11. For example, the temperature sensor may be attached to one surface of the power supply 11 (e.g., a battery) and/or mounted on one surface of a printed circuit board. For example, the aerosol generating device 1 may include a power protection circuit module (PCM), and the temperature sensor may be disposed adjacent to the power supply 11 together with the power PCM.

According to an embodiment, the temperature sensor may be disposed inside a housing (not shown) of the aerosol generating device 1 to detect an internal temperature of the housing.

According to an embodiment, the puff sensor may detect a puff of a user.

For example, the puff sensor may include a pressure sensor. The pressure sensor may output a signal corresponding to an internal pressure of the aerosol generating device 1, and the controller 12 may detect the puff of the user, based on the signal corresponding to the internal pressure. The internal pressure of the aerosol generating device 1 may correspond to pressure of an airflow path along which gas flows. The puff sensor may be disposed to correspond to the airflow path along which gas flows, in the aerosol generating device 1.

As another example, the puff sensor may include a temperature sensor. When the user's puff occurs, a temporary temperature drop may occur in the airflow path, a space where an aerosol generating article is inserted (hereinafter, an insertion space), the heater 18, etc. The controller 12 may detect the user's puff, based on a signal corresponding to the temperature of the airflow path, etc. output from the temperature sensor.

As another example, the puff sensor may include both a pressure sensor and a temperature sensor. In this case, the temperature sensor may measure a temperature that is used to correct an internal pressure measured by the pressure sensor. For example, the puff sensor may correct the signal corresponding to the internal pressure, based on the temperature measured by the temperature sensor, and may output the corrected signal. As another example, the puff sensor may output the signal corresponding to the temperature measured by the temperature sensor, and the signal corresponding to the internal pressure measured by the puff sensor. In this case, the controller 12 may receive the signals, and may correct the signal corresponding to the internal pressure, based on the signal corresponding to the temperature.

As another example, the puff sensor may include a capacitance sensor. In the present disclosure, the capacitance sensor may also be referred to as a cap sensor or a capacitive sensor. When the user's puff occurs, a temperature change and/or aerosol flow may occur within the insertion space of the aerosol generating article, and accordingly, an internal permittivity of the insertion space may change. The controller 12 may detect the user's puff, based on a signal corresponding to the internal permittivity, etc. of the insertion space output by the temperature sensor.

The puff sensor is not limited to the aforementioned examples, and may be implemented using various sensors for detecting the user's puff.

According to an embodiment, the insertion detection sensor may detect insertion and/or removal of the aerosol generating article. The insertion detection sensor may be provided around the insertion space. The insertion detection sensor may also include any combination of the aforementioned examples.

For example, the insertion detection sensor may include a capacitance sensor. The capacitance sensor may include at least one conductor. The at least one conductor may be arranged adjacent to the insertion space. When the aerosol generating article is inserted into or removed from the insertion space, a permittivity around the conductor may change. The controller 12 may detect the insertion and/or removal of the aerosol generating article, based on a signal corresponding to the internal permittivity, etc. of the insertion space output by the capacitance sensor.

As another example, the insertion detection sensor may include an inductive sensor. The inductive sensor may include at least one coil. The at least one coil may be disposed adjacent to the insertion space. When the aerosol generating article (e.g., a wrapper of the aerosol-generating article) includes a conductor and is inserted into or removed from the insertion space, a change in a magnetic field may occur around a coil where a current flows. The controller 12 may detect insertion and/or removal of the aerosol generating article including the conductor, based on the characteristics (e.g., a frequency, a current value, a voltage value, an inductance value, and an impedance value of an alternating current) of a current output or detected by the inductive sensor. Alternatively, the aerosol generating article (e.g., a medium portion of the aerosol generating article) may include a susceptor (SUS), etc. Even in this case, a change in the magnetic field around the coil may occur based on the insertion or removal of the susceptor, etc. within the insertion space, and the controller 12 may also detect the insertion and/or removal of the aerosol generating article, based on the characteristics of the current of the inductive sensor.

The insertion detection sensor is not limited to the aforementioned examples, and may be implemented using any of various sensors (e.g., a proximity sensor) for detecting insertion and/or removal of the aerosol generating article. The insertion detection sensor may also include any combination of the aforementioned examples. According to an embodiment, the insertion detection sensor may include a switch, etc. for detecting compression performed by the aerosol generating article.

According to an embodiment, the reuse detection sensor may detect whether the aerosol generating article is reused For example, the reuse detection sensor may be a color sensor for detecting a color of the aerosol generating article. When the aerosol generating article is used by the user, a change in the color of a portion of the wrapper surrounding the outside of the aerosol generating article may occur due to generated aerosol or heating. The color sensor may output a signal corresponding to optical characteristics (e.g., a wavelength of light) corresponding to the color of the wrapper, based on light reflected by the wrapper. When a change in the color of the portion of the wrapper is detected, the controller 12 may determine that the aerosol generating article inserted into the insertion space has already been used.

According to an embodiment, the overwetting detection sensor may detect whether the aerosol generating article is in an overwetting state. For example, the overwetting detection sensor may include a capacitance sensor. The capacitance sensor may include at least one conductor disposed adjacent to the insertion space. The controller 12 may detect whether the aerosol generating article is in an overwetting state, based on the level of a signal corresponding to a permittivity, etc. output by the capacitance sensor. For example, the controller 12 may check a level range including the level of the signal, based on a look-up table, and may determine a moisture content for the aerosol generating article, based on the checked level range.

According to an embodiment, the cigarette identification sensor may detect whether the aerosol generating article is authentic, and/or detect the type of the aerosol generating article.

For example, the cigarette identification sensor may include an optical sensor for detecting an identification material (or an identification mark) located on an outer surface (e.g., a wrapper) of the aerosol generating article. The optical sensor may radiate light toward the identification material (or the identification mark) of the aerosol generating article, and may detect the authenticity and/or the type of the aerosol generating article, based on the reflected light. For example, the identification material may include a material that emits light of a wavelength in a specific band, based on the radiated light. The controller 12 may detect the authenticity and/or the type of the aerosol generating article, based on the range of the wavelength.

As another example, the cigarette identification sensor may include a capacitance sensor. According to the types of aerosol generating article inserted into the insertion space, the internal permittivity of the insertion space may vary. The controller 12 may detect he authenticity of and/or the type of the aerosol generating article, based on the signal corresponding to the internal permittivity, etc. of the insertion space output by the capacitance sensor.

As another example, the cigarette identification sensor may include an inductive sensor. When a conductor is included in the wrapper and/or interior (e.g., a medium portion) of the aerosol generating article inserted into the insertion space, the characteristics of a current detected by the inductive sensor (e.g., a frequency, a current value, a voltage value, an inductance value, and an impedance value of an AC current) may differ according to the types of aerosol generating article inserted into the insertion space. The controller 12 may detect he authenticity of and/or the type of the aerosol generating article, based on the characteristics of a current output by the capacitance sensor or detected by the inductive sensor.

The cigarette identification sensor is not limited to the aforementioned examples, and may be implemented using any of various sensors for detecting whether the aerosol generating article is authentic, and/or detecting the type of the aerosol generating article. The cigarette identification sensor may also include any combination of the aforementioned examples.

According to an embodiment, the cartridge detection sensor may detect insertion and/or removal of the cartridge. For example, the cartridge detection sensor may include an inductive sensor, a capacitance sensor, a resistance sensor, a hall sensor (a hall IC) using a hall effect, and/or an optical sensor.

According to an embodiment, the cap detection sensor may detect insertion and/or removal of the cap. For example, the cap detection sensor may include an inductive sensor, a capacitance sensor, a resistance sensor, a hall sensor (a hall IC), and/or an optical sensor. The cap may include a structure that covers at least a portion of the cartridge mounted on or inserted into the aerosol generating device 1 or covers at least a portion of the housing of the aerosol generating device 1. When the cap is mounted on or removed from the housing, the cap detection sensor may output a signal corresponding to the mounting or removal of the cap. The controller 12 may detect the mounting or removal of the cap, based on a signal corresponding to the mounting or removal.

According to an embodiment, the movement detection sensor may detect a motion of the aerosol generating device 1. The movement detection sensor may be implemented using at least one of an acceleration sensor and a gyro sensor.

According to an embodiment, the sensor unit 13 may further include at least one of a humidity sensor, a pressure sensor, a magnetic sensor, a global positioning sensor (GPS), or a proximity sensor, in addition to the above-described sensors. Functions of the sensors would be instinctively understood by one of ordinary skill in the art in view of their names and thus detailed descriptions thereof will be omitted herein.

According to an embodiment, the output unit 14 may output information about the state of the aerosol generating device 1. The output unit 14 may include a display, a haptic unit, and/or a sound output unit, but embodiments are not limited thereto. For example, information about the aerosol generating device 1 may include a charging/discharging state of the power supply 11 of the aerosol generating device 1, preheating states of the heater 18, an insertion/removal state of the aerosol generating article and/or the cartridge, a mounting and/or removal state of the cap, or a state in which use of the aerosol generating device 1 is limited (e.g., detection of an abnormal article). The display may visually provide the information about the state of the aerosol generating device 1 to the user. For example, the display may include a light-emitting diode (LED), a liquid crystal display (LCD), an organic light-emitting diode (OLED), etc. When the display includes a touch pad, the display may also be used as an input unit 15. A haptic unit may tactually provide the information about the state of the aerosol generating device 1 to the user. For example, the haptic unit may include a vibration motor, a piezoelectric element, an electrical stimulation device, etc. The sound output unit may acoustically provide the information about the aerosol generating device 1 to the user. For example, the sound output unit may convert an electrical signal into a sound signal and may output the sound signal to the outside.

According to an embodiment, the power supply 11 may output power for operating the aerosol generating device 1. The power supply 11 may include one or more batteries. The power supply 11 may supply power so that the heater 18 may be heated. In addition, the power supply 11 may supply power required for operations of the controller 12, the sensor unit 13, the output unit 14, the input unit 15, the communication unit 16, the memory 17, etc. which are other components included in the aerosol generating device 1. The power supply 11 may be a rechargeable battery or a disposable battery. For example, the power supply 11 may be a lithium polymer (LiPoly) battery, but embodiments are not limited thereto. The power supply 11 may be a rechargeable (separate-type) battery (hereinafter, a detachable battery. The detachable battery may be mounted on a battery accommodation part provided within the aerosol generating device 1, or may be removed from the battery accommodation part. The detachable battery may be charged either via wire or wirelessly.

According to an embodiment, the heater 18 may heat a medium and/or an aerosol generating material within the aerosol generating article and/or the cartridge by receiving power from the power supply 11. The aerosol generating device 1 may include a heater 18 for heating the aerosol generating article and/or a cartridge heater for heating the cartridge (i.e., a solid and/or liquid medium).

According to an embodiment, the heater 18 may be electro-resistive heaters. For example, the electro-resistive heaters may include an electro-resistive material, such as a metal including titanium, zirconium, tantalum, platinum, nickel, cobalt, chromium, hafnium, niobium, molybdenum, tungsten, tin, gallium, manganese, iron, copper, stainless steel, nichrome, or the like, or a metal alloy. The electro-resistive heaters may be implemented using a metal heating wire, a metal heating plate on which an electric conductive track is disposed, a ceramic heating body, or the like.

According to an embodiment, the heater 18 may be induction heating heaters. For example, the induction heating heaters may include a susceptor that generates heat through a magnetic field. The magnetic field may be generated from an induction coil by an AC current flowing through the induction coil. The generated magnetic field may penetrates a heater and an eddy current may be generated by the susceptor. The susceptor may be heated based on the generation of the eddy current. According to an embodiment, the susceptor may be included within the aerosol generating article (e.g., the medium portion). Even in this case, the susceptor included within the aerosol generating article may be heated by the induction coil.

The heater 18 are not limited to the aforementioned examples, and may include or be replaced with various heating methods, structures, components, etc. for heating the aerosol generating article and/or the cartridge.

According to an embodiment, the input unit 15 may receive information input by the user. For example, the input unit 15 may include a touch panel, a button, a keypad, a dome switch, a jog wheel, a jog switch, etc.

According to an embodiment, the memory 17 is hardware for storing various kinds of data processed in the aerosol generating device 1, and may store pieces of data that have been processed and are to be processed by the controller 12. For example, the memory 17 may include at least one type of storage medium selected from among a flash memory type, a hard disk type, a multimedia card micro type, a card type memory (for example, a secure digital (SD) or extreme digital (XD) memory), a random access memory (RAM), a static random access memory (SRAM), a read-only memory (ROM), an electrically erasable programmable ROM (EEPROM), a programmable ROM (PROM), magnetic memory, a magnetic disk, and an optical disk. For example, the memory 17 may store data about an operating time of the aerosol generating device 1, a maximum number of puffs, a current number of puffs, at least one temperature profile, and the user's smoking pattern.

According to an embodiment, the communication unit 16 may include at least one component for communication with another electronic device (e.g., a portable electronic apparatus). For example, the communication unit 16 may include a Bluetooth communication unit, a Bluetooth Low Energy (BLE) communication unit, an Near Field Communication (NFC) communication unit, a wireless local area network (WLAN) communication unit, a ZigBee communication unit, an infrared Data Association (IrDA) communication unit, a Wireless Fidelity Direct (WFD) communication unit, an ultra wideband (UWB) communication unit, an Adaptive Network Topology (Ant)+ communication unit, a cellular network communication unit, an Internet communication unit, a computer network (e.g., a LAN or WAN) communication unit, etc.

According to an embodiment, the controller 12 may control overall operations of the aerosol generating device 1. For example, the controller 12 may include at least one processor. The controller 12 may be implemented as an array of a plurality of logic gates, or as a combination of a general-use micro controller unit (MCU) (or a microprocessor) and a memory in which a program executable by the general-use MCU is stored. It will also be understood by one of ordinary skill in the art to which the present embodiment pertains that the controller 12 may be implemented as other types of hardware.

According to an embodiment, the controller 12 may control supplying of the power of the power supply 11 to the heater 18, thereby controlling the temperatures of the heater 18. The controller 12 may control the temperatures of the heater 18 and/or power supplied to the heater 18, based on the temperatures of the heater 18 detected using the temperature sensor (e.g., the sensor unit 13). The controller 12 may control the temperatures of the heater 18 and/or the power supplied to the heater 18, based on a temperature profile and/or a power profile stored in the memory 17.

According to an embodiment, the controller 12 may control power (e.g., a voltage and/or a current) supplied to the heater 18 by controlling a power conversion circuit (not shown) electrically connected to the heater 18 and the power supply 11. For example, the power conversion circuit may include a DC/DC converter (e.g., a buck converter, a buck-boost converter, a boost converter, or a Zener diode) that converts power that is to be supplied to the heater 18, and a DC/AC converter (e.g., an inverter) that converts power that is to be supplied to an induction coil (not shown). The DC/AC inverter may be implemented as a full-bridge circuit or half-bridge circuit including a plurality of switching elements. For example, the power conversion circuit may include at least one switching element, such as a bipolar junction transistor (BJT) and a field effect transistor (FET).

According to an embodiment, the controller 12 may control the current and/or voltage supplied to the heater 18 by controlling the frequency and/or duty ratio of a current pulse input to the at least one switching element of the power conversion circuit. A duty ratio with respect to an on/off operation of the switching element may correspond to a ratio of an output voltage of the power conversion circuit to an output voltage of the power supply 11.

According to an embodiment, the controller 12 may control power that is supplied to the heater 18, by using at least one method among a pulse width modulation (PWM) method and a proportional-integral-differential (PID) method. For example, the controller 12 may control a current pulse having a certain frequency and a duty ratio to be supplied to the heater 18, by using the PWM method. The controller 12 may control the power supplied to the heater 18, by adjusting the frequency and duty ratio of the current pulse. For example, the controller 12 may determine a target temperature that is a target of control, based on the temperature profile. The controller 12 may control the power supplied to the heater 18, by using a PID method, which is a feedback control method using a difference value between the temperatures of the heater 18 and the target temperature thereof, a value obtained by integrating the difference value according to the flow of time, and a value obtained by differentiating the difference value according to the flow of time.

According to an embodiment, the controller 12 may determine target power that is a target of control, based on the power profile. The controller 12 may control the power supplied to the heater 18 to correspond to preset target power, according to the flow of time.

According to an embodiment, the controller 12 may detect the user's puff by detecting the power supplied to the heater 18. In more detail, the controller 12 may control the power supplied to the heater 18, by using the PID method. When the user's puff occurs, a temporary temperature drop may occur in a space where the aerosol generating article is inserted (hereinafter, the insertion space), the heater 18, etc. Accordingly, a change may occur in the power (or current) supplied to the heater 18 during power control using the PID method. The controller 12 may detect the user's puff, based on a change in the power that is controlled.

According to an embodiment, the controller 12 may prevent the heater 18 from being heated. For example, the controller 12 may control an operation of the power conversion circuit so that the amount of the power supplied to the heater 18 is reduced or the power supply to the heater 18 is stopped, based on the temperatures of the heater 18 exceeding a preset limit temperature.

According to an embodiment, the controller 12 may control charging/discharging of the power supply 11. For example, the controller 12 may check the temperature of the power supply 11 by using the temperature sensor (e.g., the sensor unit 13). When the temperature of the power supply 11 is equal to or greater than a first limit temperature, the controller 12 may block charging of the power supply 11. When the temperature of the power supply 11 is greater than or equal to a second limit temperature, the controller 12 may stop using (e.g., discharging) the power stored in the power supply 11. The controller 12 may calculate the remaining capacity of the power stored in the power supply 11. For example, the controller 12 may calculate the remaining capacity of the power supply 11, based on a voltage and/or current sensing value of the power supply 11.

According to an embodiment, the controller 12 may control supply of power to the heater 18, based on a result of the sensing performed by the sensor 13.

According to an embodiment, the controller 12 may control supply of power to the heater 18, based on insertion and/or removal of the aerosol generating article into and/or the insertion space. For example, when it is determined using the insertion detection sensor (e.g., the sensor unit 13) that the aerosol generating article has been inserted into the insertion space, the controller 12 may control power to be supplied to the heater 18. When it is determined using the insertion detection sensor (e.g., the sensor unit 13) that the aerosol generating article has been removed from the insertion space, the controller 12 may block the supply of power to the heater 18. When the temperatures of the heater 18 are equal to or greater than a limit temperature or temperature change slopes of the heater 18 are equal to or greater than a set slope, the controller 12 may determine that the aerosol generating article has been removed from the insertion space.

According to an embodiment, the controller 12 may control power supply time periods and/or power supply amounts for the heater 18, based on the state of the aerosol generating article. For example, when it is determined using the overwetting detection sensor (e.g., the sensor unit 13) that the aerosol generating article is in an overwetting state, the controller 12 may increase the power supply time periods (e.g., preheating time periods) for the heater 18.

According to an embodiment, the controller 12 may control supply of power to the heater 18, based on reuse or non-reuse of the aerosol generating article. For example, when it is determined that the aerosol generating article has been used, the controller 12 may block supply of power to the heater 18.

According to an embodiment, the controller 12 may control supply of power to the heater 18, based on attachment and/or removal of the cartridge. For example, when it is determined using the cartridge detection sensor (e.g., the sensor unit 13) that the cartridge is in a separated state, the controller 12 may block supply of power to the heater 18 or may control power to be not supplied to the heater 18.

According to an embodiment, the controller 12 may control supply of power to the heater 18, based on whether the aerosol generating material of the cartridge has been exhausted. For example, when it is determined that the temperatures of the heater 18 exceed the limit temperature while the heater 18 are being preheated (i.e., in a preheating section), the controller 12 may determine that the aerosol generating material in the cartridge has been exhausted. When it is determined that the aerosol generating material of the cartridge has been exhausted, the controller 12 may cut off the supply of power to the heater 18.

According to an embodiment, the controller 12 may control the supply of power to the heater 18, based on whether use of the cartridge is possible. For example, when it is determined based on data stored in the memory 17 that a current number of puffs is equal to or greater than a maximum number of puffs set in the cartridge, the controller 12 may determine that the use of the cartridge is not possible. For example, when a total time period during which the heater 18 are heated is greater than or equal to a preset maximum time period or a total amount of power supplied to the heater 18 is greater than or equal to a preset maximum power amount, the controller 12 may determine that the use of the cartridge is not possible. In this case, the controller 12 may block supply of power to the heater 18 or may control power to be not supplied to the heater 18.

According to an embodiment, the controller 12 may control the supply of power to the heater 18, based on the user's puff. For example, the controller 12 may determine occurrence or non-occurrence of a puff and/or the intensity of the puff, by using the puff sensor (e.g., the sensor unit 13). When the number of puffs reaches the preset maximum of puffs or puffs are not sensed for a preset time period or more, the controller 12 may cut off the supply of power to the heater 18. When a puff is sensed, the controller 12 may control the supply of power to the heater 18.

According to an embodiment, the controller 12 may control supply of power to the heater 18, based on authenticity of the aerosol generating article (or the cartridge) and/or the type of the aerosol generating article. For example, the controller 12 may detect authenticity or of the aerosol generating article and/or the type of the aerosol generating article, by using the cigarette identification sensor (e.g., the sensor unit 13). For example, when the aerosol generating article (or the cartridge) is detected as counterfeit, the controller 12 may block supply of power to the heater 18. When the aerosol generating article (or the cartridge) is detected as authentic, the controller 12 may control (e.g., start) supply of power to the heater 18. As another example, the controller 12 may differently control power supply to the heater 18 according to the types of aerosol generating article (or cartridge). In more detail, when the aerosol generating article (or the cartridge) is detected as a first aerosol generating article (or a first cartridge), the controller 12 may control the temperatures and/or power of the heater 18, based on a first temperature profile (or a first power profile), and, when the aerosol generating article (or cartridge) is detected as a second aerosol generating article (or a second cartridge), may control the temperatures and/or power of the heater 18, based on a second temperature profile (or a second power profile).

According to an embodiment, the controller 12 may control the output unit 14, based on a result of the sensing performed by the sensor unit 13. For example, when the number of puffs counted using the puff sensor (e.g., the sensor unit 13) reaches a preset number, the controller 12 may control the output unit 14 to visually, tactually, and/or acoustically provide information indicating that the aerosol generating device 1 is about to be terminated. For example, the controller 12 may control the output unit 14 to visually, tactually, and/or acoustically provide information about the temperatures of the heater 18.

According to an embodiment, the controller 12 may store and update a history of an event occurred in the memory 17, based on certain event occurrence. For example, the event may include insertion detection of the aerosol generating article, heating start of the aerosol generating article, puff detection, puff end, overheat detection of the heater 18, detection of overvoltage application to the heater 18, heating end of the aerosol generating article, an operation such as power on/off of the aerosol generation device 1, charging start of the power supply 11, detection of overcharging of the power supply 11, and charging end of the power supply 11, which are performed by the aerosol generating device 1. For example, the history of the event may include, for example, a date and time of the event, and log data corresponding to the event. For example, when a predetermined event is insertion detection of the aerosol generating article, log data corresponding to the event may include data for a sensing value, etc. of the insertion detection sensor (e.g., the sensor unit 13). For example, when the predetermined event is overheating detection of the heater 18, the log data corresponding to the event may include data about, for example, the temperature of the heater 18, the voltage applied to the heater 18, and the current flowing through the heater 18.

According to an embodiment, the controller 12 may control the communication unit 16 to form a communication link with an external device, such as the user's mobile terminal.

According to an embodiment, when receiving data on authentication from the external device through the communication link, the controller 12 may dismiss limitation of the use of at least one function (e.g., a heating function) of the aerosol generating device 1. For example, the data on authentication may include the user's birthday, a unique number representing the user, and completion or non-completion of authentication of the user.

According to an embodiment, the controller 12 may transmit data on the state of the aerosol generating device 1 (e.g., a remaining capacity of the power supply 11, and an operating mode) to the external device via the communication link. The transmitted data may be output through, for example, a display of the external device.

According to an embodiment, when a request for a location search of the aerosol generating device 1 is received from the external device via the communication link, the controller 12 may control the output unit 14 to perform an operation corresponding to the location search. For example, the controller 12 may control the haptic unit to generate vibration, or may control the display to output an object corresponding to the location search and a search end.

According to an embodiment, when receiving firmware data from the external device via the communication link, the controller 12 may perform firmware update.

According to an embodiment, the controller 12 may transmit data on a sensing value of at least one sensor unit 13 to an external server (not shown) through the communication link, and may receive and store a learning model generated by learning sensing values from a server through machine learning, such as deep learning. The controller 12 may perform, for example, an operation of determining the user's inhaling pattern and an operation of generating a temperature profile, by using the learning model received from the server.

Although not shown in FIG. 1, the aerosol generating device 1 may further include a power supply protection circuit. The power protection circuit may include at least one switching element, and may cut off transmission path to the power supply 11 in response to overcharging and/or overdischarging of the power supply 11. The aerosol generating device 1 may further include a connection interface, such as a universal serial bus (USB) interface, and may transmit/receive information by being connected to another external device through the connection interface, or may charge the power supply 11.

The aerosol generating article as described herein may include at least one aerosol generating rod (e.g., a medium portion) and at least one filter rod. The heater 18 may be arranged to correspond to the at least one aerosol generating rod, and may be designed differently according to arrangement orders and/or locations of the aerosol generating rod and the filter rod. The aerosol generating rod may include at least one of nicotine, an aerosol generating material, and additives. For example, the aerosol generating material may include glycerin (e.g., vegetable glycerin (VG)) and/or propylene glycol (PG), but may also include various other materials. For example, the additives may include flavors and/or organic acid, and may also include various other materials. For example, the aerosol generating rod may include an aerosol generating substrate (e.g., a sheet) impregnated with a liquid non-tobacco material (e.g., an aerosol generating material and/or nicotine), and/or may include a solid tobacco material (e.g., leaf tobacco and reconstituted tobacco). The tobacco material may be included in the aerosol generating rod in various forms, such as Cut Tobacco, granules, or powder. According to an embodiment, the additives of the aerosol generating rod may include an alkaline substance. Based on the basic material, the nicotine of the tobacco material included in the aerosol generating rod may have an alkaline pH (e.g., pH 7.0 or higher). In this case, freebase nicotine may be released from the aerosol generating rod even at low temperature. According to an embodiment, the aerosol generating rod may include two or more aerosol generating rods, wherein the two or more aerosol generating rods may include a tobacco material and/or a non-tobacco material, respectively. Although not shown, at least one aerosol generating rod and at least one filter rod may be individually and/or integrally wrapped by at least one wrapper. In the disclosure, the aerosol generating article may be referred to as a stick.

The cartridge mentioned in the disclosure may contain an aerosol generating material in any one state among a liquid state, a solid state, a gaseous state, a gel state, and the like. The aerosol generating material may include a liquid composition. For example, the liquid composition may be a liquid including a tobacco-containing material having a volatile tobacco flavor component, or may be a liquid including a non-tobacco material. The cartridge may include a storage containing an aerosol generating material and/or a liquid delivery unit impregnated with (containing) the aerosol-generating material. For example, the liquid delivery unit may include a wick or the like, such as a cotton fiber, a ceramic fiber, a glass fiber, or porous ceramic. The cartridge heater may be included in the cartridge, as a coil-shaped structure that is wound around the liquid delivery unit or in a structure in contact with one side of the liquid delivery unit. Alternatively, the cartridge heater may be included in an aerosol generating device 1 that is separable from the cartridge.

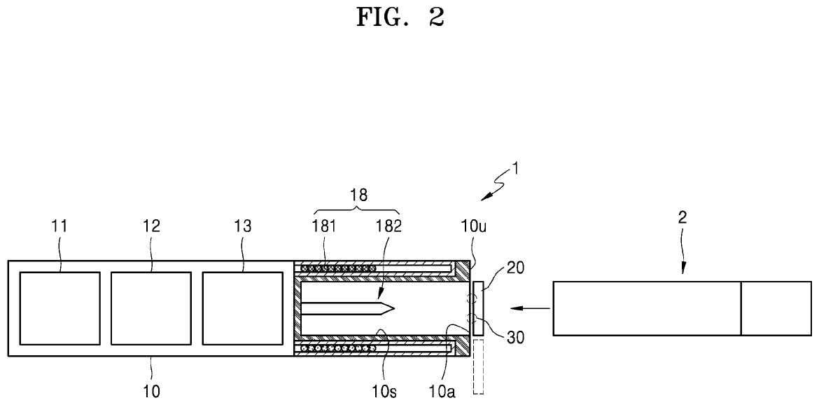

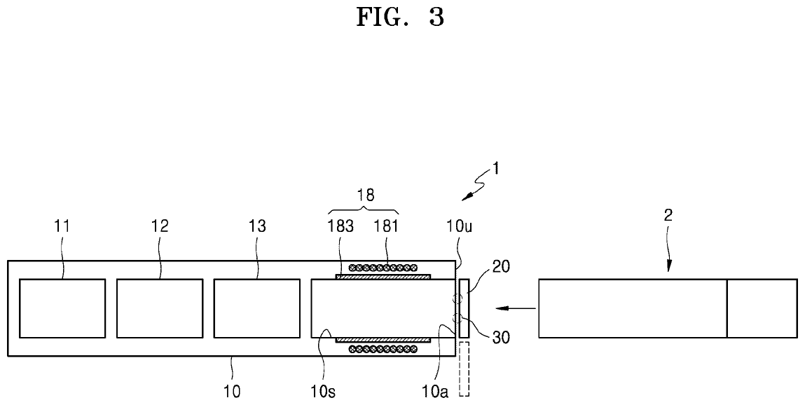

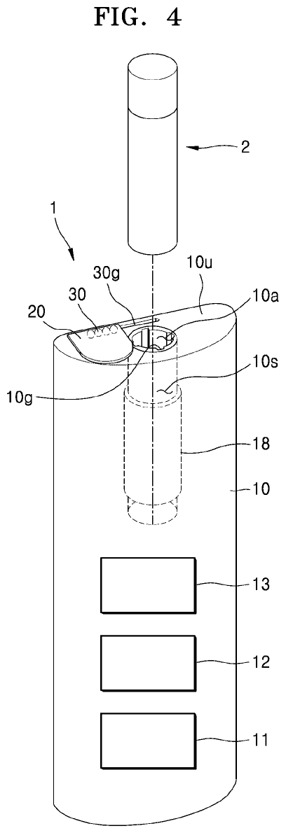

FIG. 2 illustrates an aerosol generating device according to an embodiment. FIG. 3 illustrates an aerosol generating device 1 according to another embodiment. FIG. 4 is a perspective view of an aerosol generating device 1 according to the embodiment illustrated in FIG. 3.

According to an embodiment shown in FIGS. 2 and 3, the aerosol generating device 1 may include a housing 10, the power supply 11, the controller 12, the sensor unit 13, and/or a heater 18 (e.g., the heater 18 of FIG. 1). However, the components included in the aerosol generating device 1 are not limited to those shown in FIGS. 2 to 4. It may be understood by those skilled in the art that some of the components shown in FIGS. 2 to 4 may be omitted or new components may be added. The aerosol generating device 1 illustrated in FIG. 2 may be referred to as an ‘internal heating type’ aerosol generating device that heats the inside of an aerosol generating article 2. The aerosol generating device 1 illustrated in FIGS. 3 and 4 may be referred to as an ‘external heating type’ aerosol generating device that heats the outside of the aerosol generating article 2. In the drawings below, any description that overlaps with FIG. 1 will be omitted.

According to an embodiment, the housing 10 may provide a space opened upward so that the aerosol generating article 2 may be inserted. In the disclosure, the upwardly-opened space may be referred to as an insertion space 10s. The insertion space 10s may be recessed toward the inside of the body 10 by a certain depth so that at least a portion of the aerosol generating article 2 may be inserted thereinto. The depth of the insertion space may be equal to or greater than a length of a region in the aerosol generating article 2, in which an aerosol generating material and/or a medium is included. A lower end of the aerosol generating article 2 may be inserted into the housing 10, and an upper end of the aerosol generating article 2 may protrude to the outside of the housing 10. A user may inhale aerosol by holding, in his or her mouth, the upper end of the aerosol generating article 2 exposed to the outside.

Referring to FIGS. 2 to 4, the housing 10 may include an outer surface 10u to which a door 20 is coupled. An opening 10a that opens toward the outside may be formed in the outer surface 10u of the housing 10. An insertion space 10s of the aerosol generating device 1 communicates with the opening 10a. At least a portion of the aerosol generating article 2 may be inserted into the insertion space 10s within the aerosol generating device 1 through the opening 10a.

Referring to FIG. 4, the insertion space 10s may include an air inlet 10g that allows external air to enter the aerosol generating device 1.

Referring to FIGS. 2 to 4, the aerosol generating device 1 may include the door 20 that opens or closes the opening 10a. The door 20 is movable relative to the housing 10.

Referring to FIG. 4, a guide hole 30g may be formed in the outer surface 10u of the aerosol generating device 1. The guide hole 30g may extend in a movement direction of the door 20. The door 20 may be guided by the guide hole 30g to move along the outer surface 10u.

The door 20, depicted in solid lines in FIGS. 2 and 3, is positioned in a closed position to close the opening 10a. The door 20, depicted in a dotted line, is positioned in an open position to open the opening 10a.

A bearing 30 may be arranged between the door 20 and the housing 10. The bearing 30 may support the door 20 so that the door 20 may move relative to the housing 10. While the door 20 moves relative to the housing 10, the bearing 30 may rotates, thereby supporting the door 20.

According to the embodiments described above, because the door 20 is supported by the bearing 30, the movement of the door 20 relative to the housing 10 may be smoothly realized. With the structure in which the door 20 is movably supported by the bearing 30, direct friction between the door 20 and the housing 10 may be reduced Therefore, even when the door 20 is repeatedly used, wear and damage to components related to the operation of the door 20 may be reduced.

According to an embodiment, the heater 18 may heat the aerosol generating article 2.

Referring to FIG. 2, the heater 18 may be implemented as an internal heating heater 182.

According to an embodiment, the internal heating heater 182 may extend long upward in a space (i.e., the insertion space 10s) into which the aerosol generating article 2 is inserted. For example, the internal heating heater may include a rod-shaped heating element or a needle-shaped heating element. However, the internal heating heater may include any of various heating elements, such as a tube-shaped heating element or a plate-shaped heating element. The internal heating heater may be inserted through a lower side of the aerosol generating article 2.

According to an embodiment, the internal heating heater may include an electrically resistive heater and/or an induction heating heater.

For example, the electrically resistive heater may include an electrically resistive material on the inside (e.g., an inner hollow or an inner surface) or the outside (e.g., an outer surface), and may be heated as a current flows through the electrically resistive material. In this case, the electrically resistive heater may be electrically connected to the power supply 11, and may directly generate heat by receiving a current from the power supply 11. An induction coil 181 may be omitted.

For example, in the case of induction heating heaters, the aerosol generating device 1 may include the induction coil 181 surrounding at least a portion of the internal heating heater 182 (e.g., being positioned outside to correspond to a length of at least a portion of the heater). In this case, a magnetic flux concentrator, etc. may be further included on the outside of the induction coil 181 in order to increase the efficiency of induction heating. An induction heating heater may include a susceptor, and may generate heat based on a magnetic field generated by the induction coil 181. According to an embodiment, the internal heating heater 182 being an induction heater (e.g., a susceptor) (or a heater module including the induction heating heater) may be arranged to be detachable from the housing 10.

According to an embodiment, the heater 18 may be multiple heaters. The multiple heaters may include a first heater and a second heater, and may be inserted into the aerosol generating article 2. The first heater and the second heater may be arranged side by side along a longitudinal direction. The first heater and the second heater may operate as electrically resistive heaters and/or induction heating heaters, and may be sequentially heated or may be simultaneously heated. In this case, the first heater and the second heater may be respectively arranged at locations corresponding to longitudinal locations of two or more aerosol generating rods. Alternatively, the first heater and the second heater may be respectively arranged at locations corresponding to longitudinal locations of a first portion and a second portion of one aerosol generating rod. When the heater 18 is an induction heating heater, the aerosol generating device 1 may include a first induction coil and a second induction coil, and the first induction coil and the second induction coil may be respectively arranged at locations corresponding to longitudinal locations of the first heater and the second heater. Alternatively, the first heater and the second heater may be respectively arranged at locations corresponding to longitudinal locations of a first portion and a second portion of the one heater 18. Three or more heaters and/or three or more induction coils may be included.

According to an embodiment, a susceptor may be disposed (or included) in the inside (e.g., the medium portion) of the aerosol generating article 2, and the susceptor included within the aerosol generating article 2 may be implemented to generate heat, based on the magnetic field generated by the induction coil 181.

Referring to FIG. 3, the heater 18 may be an external heating heater 183.

According to an embodiment, the external heating heater 183 may extend long upward around a space (i.e., the insertion space 10s) into which the aerosol generating article 2 is inserted. For example, the external heating heater 183 may be disposed to surround at least a portion of the insertion space 10s. For example, the external heating heater 183 may include a tubular shape (e.g., a cylindrical shape) including a hollow therein. The external heating heater 183 may have a shape including a hollow on the inside and surrounding the hollow. In this case, the external heating heater 183 may be supported by a polyimide film. A heater supported by such a film may be referred to as a film heater. The external heating heater 183 may be disposed to surround at least a portion of the insertion space 10s. The external heating heater 183 may heat the outside of the aerosol generating article 2 inserted into the insertion space 10s.

According to an embodiment, the external heating heater may include an electrically resistive heater and/or an induction heating heater. A description of FIG. 3 that overlaps with FIG. 2 will be omitted. In the case of induction heating heaters, the aerosol generating device 1 may include an external heating heater 183 implemented as a tube-shaped susceptor, and may include the induction coil 181 surrounding at least a portion of the external heating heater 183 (e.g., being positioned outside to correspond to a length of at least a portion of the heater). The induction coil 181 may include a fan coil. When the external heating heater 183 is an electrically resistive heater, heat generation is possible through a current flow on a tube-shaped electrically resistive heater (e.g., a film heater), and thus the separate induction coil 181 may be omitted. Insulation may also be disposed on the outside of the external heating heater 183. Accordingly, the heat radiated outward by the heater 18 and applied to the outside of the housing 10 may be reduced.

According to one embodiment, the heater 18 may be multiple heaters, and the first heater and the second heater may be arranged side by side along the longitudinal direction so as to each surround at least a portion of the insertion space. The first heater and the second heater may operate as electrically resistive heaters and/or induction heating heaters, and may be sequentially heated or may be simultaneously heated. When the heater 18 is an induction heating heater, the aerosol generating device 1 may include a first induction coil and a second induction coil, and the first induction coil and the second induction coil may be respectively arranged at locations corresponding to longitudinal locations of the first heater and the second heater. Alternatively, the first heater and the second heater may be respectively arranged at locations corresponding to longitudinal locations of a first portion and a second portion of the one heater 18.

Unlike what shown in FIG. 2 or FIG. 3, the internal heating heater 182 of FIG. 2 and the external heating heater 183 of FIG. 3 may be included together in the aerosol generating device 1. In this case, the internal heating heater 182 may heat the inside of the aerosol generating article 2, and the external heating heater 183 may heat the outside of the aerosol generating article 2.

According to an embodiment, the aerosol generating device 1 may be provided with an airflow channel through which air flows. For example, the housing 10 may include a structure (e.g., a hole) in which air may be introduced from the outside into the housing 10. The air introduced into the housing 10 may be introduced into the aerosol generating article 2 through the lower end (i.e., an upstream side) of the aerosol generating article 2. Aerosol generated based on the heating of the aerosol generating article 2, together with the introduced air, may be inhaled into the user's mouth through the upper end (i.e., the downstream side) of the aerosol generating article 2.

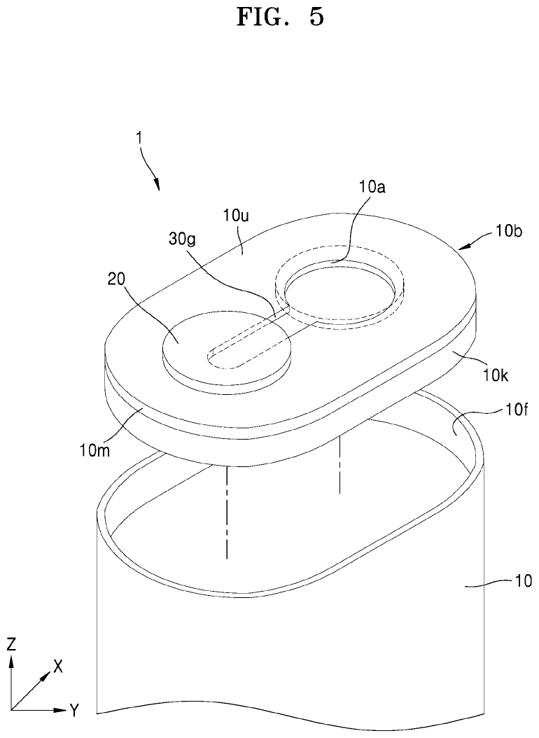

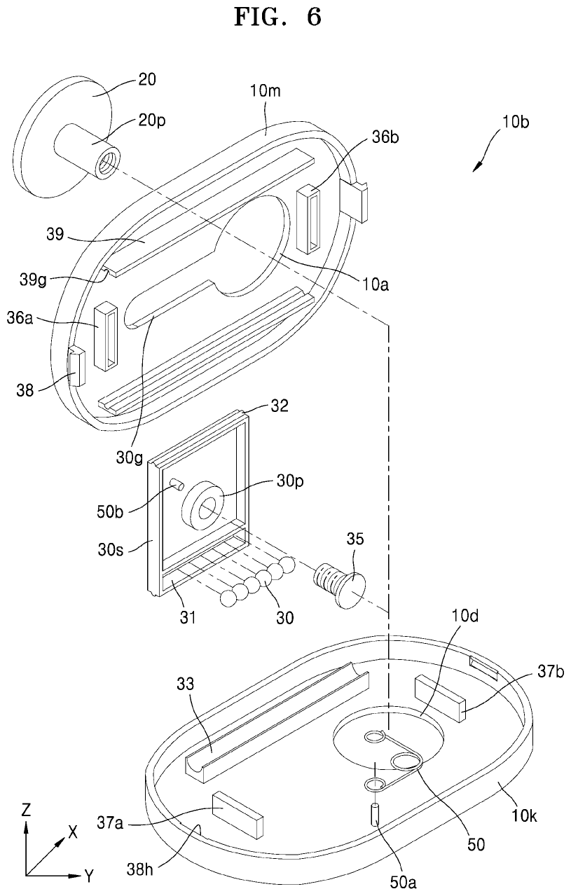

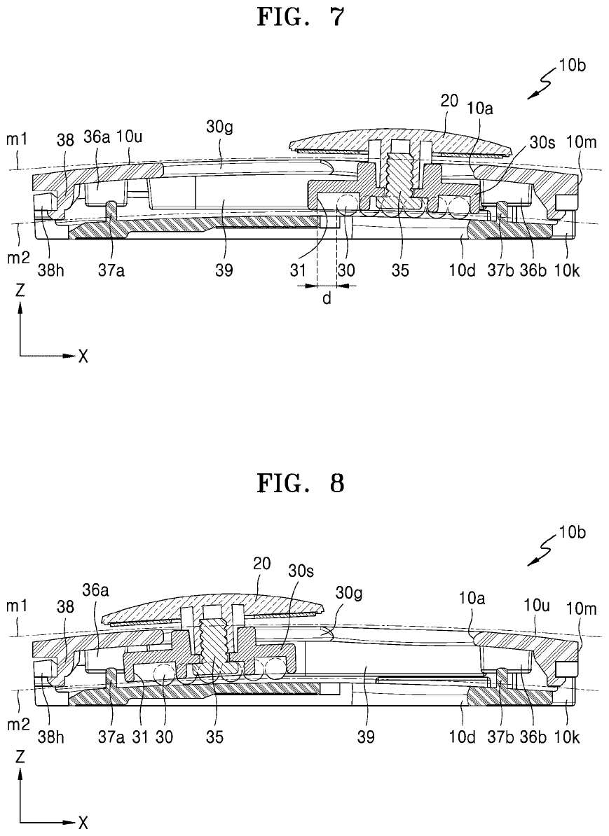

FIG. 5 is a perspective view schematically illustrating a portion of an aerosol generating device 1 according to another embodiment, FIG. 6 is an exploded perspective view illustrating elements of a door assembly 10b of the aerosol generating device 1 according to the embodiment illustrated in FIG. 5, and FIG. 7 is a longitudinal cross-sectional view of a portion of the aerosol generating device 1 according to the embodiment illustrated in FIG. 5.

A housing 10 of the aerosol generating device 1 may include a mounting opening 10f that opens toward the outside, and a door assembly 10b that is mounted on the mounting opening 10f. The housing 10 may have, for example, a hollow tubular shape. The mounting opening 10f is formed to open toward the outside at one end of the housing 10. The door assembly 10b mounted on the mounting opening 10f may movably support a door 20 relative to the housing 10.

The door assembly 10b may include an upper plate 10m and a lower plate 10k. The upper plate 10m includes an outer surface 10u to which the door 20 is coupled. The upper plate 10m includes a protrusion 38 protruding toward the lower plate 10k. The lower plate 10k includes a coupling groove 38h into which the protrusion 38 may be coupled. The protrusion 38 may include a hook that may be caught on the coupling groove 38h to maintain a coupled state of the upper plate 10m and the housing 10. When the upper plate 10m and the lower plate 10k are coupled to each other, the protrusion 38 may be supported by the coupling groove 38h, and thus, the coupling state of the upper plate 10m and the lower plate 10k may be firmly maintained.

The upper plate 10m includes an opening 10a and may movably support the door 20. The door 20 may move along the outer surface 10u of the upper plate 10m.

The lower plate 10k includes an internal opening 10d communicating with the opening 10a. A bearing support 30s supporting a bearing 30 may be arranged between the upper plate 10m and the lower plate 10k. When the upper plate 10m and the lower plate 10k are coupled to each other, a movement space in which the bearing support 30s may be placed is formed between the upper plate 10m and the lower plate 10k.

One side of the bearing support 30s may be connected to the door 20. The door 20 may include a coupling shaft 20p. The bearing support 30s may include a connecting shaft 30p corresponding to the coupling shaft 20p. A bolt 35 may pass through the connecting shaft 30p and be connected to the coupling shaft 20p. The door 20 and the bearing support 30s may be connected to each other by the bolt 35.

The upper plate 10m may include a guide hole 30g for guiding the movement of the door 20. The guide hole 30g extends in a movement direction (the X-axis direction) of the door 20. The door 20 and the bearing support 30s may be connected to each other through the guide hole 30g. For example, the coupling shaft 20p of the door 20 is connected to the bearing support 30s through the guide hole 30g.

A guide 39 is arranged between the upper plate 10m and the lower plate 10k to guide the movement of the bearing support 30s. The guide 39 may extend in the movement direction (the X-axis direction) of the door 20. The guide 39 may guide the linear movement of the bearing support 30s. For example, the bearing support 30s may include a straight protrusion 32 protruding from the side of the bearing support 30s, and the guide 39 may include a straight groove 39g into which the straight protrusion 32 is inserted. The straight protrusion 32 may extend in an extension direction of the guide 39. With the straight protrusion 32 inserted into the straight groove 39g, the bearing support 30s may move linearly along the guide 39.

The bearing support 30s supports the bearing 30 so that the bearing 30 rotates when the door 20 moves relative to the housing 10.

The upper plate 10m may include stoppers 36a and 36b protruding toward the lower plate 10k. The lower plate 10k may include fixed protrusions 37a and 37b that protrude toward the upper plate 10m and are coupled to stoppers 36a and 36b. As the stoppers 36a and 36b come into contact with the bearing support 30s, the stoppers 36a and 36b may limit the linear movement of the bearing support 30s.

A plurality of bearings 30 may be arranged between the door 20 and the housing 10. The bearing support 30s may include a bearing accommodation space 31 for accommodating the bearing 30. The bearing accommodation space 31 extends in the extension direction of the door 20. The plurality of bearings 30 may be sequentially arranged in the movement direction of the door 20. The lower plate 10k may include a movement guide 33 that contacts a portion of the surface of the bearing 30 moving together with the door 20 and guides the movement of the bearing 30. When the door 20 moves relative to the housing 10, the bearing 30 may rotate while moving together with the door 20.

The bearing 30 has a spherical shape. Embodiments are not limited by the configuration of the bearing 30. For example, the bearing 30 may have a cylindrical shape.

Referring to FIG. 7, a gap d may be formed between the inner wall of the bearing accommodation space 31 and the bearing 30. When the door 20 and the bearing support 30s move, the bearing 30 may rotate while contacting the lower surface of the bearing support 30s and the movement guide 33 of the lower plate 10k. Because the gap d is formed between the inner wall of the bearing accommodation space 31 and the bearing 30, the bearing 30 may move inside the bearing accommodation space 31. Due to the gap d formed between the inner wall of the bearing accommodation space 31 and the bearing 30, the movement and rotation of the bearing 30 moving together with the door 20 and the bearing support 30s may be smoothly performed.

Referring to FIG. 6, a pressure support 50 that presses the bearing support 30s in one direction (+X direction) or the other direction (−X direction) may be arranged between the upper plate 10m and the lower plate 10k. The pressure support 50 may include, for example, a torsion spring. One end of the pressure support 50 is connected to a first shaft 50a of the lower plate 10k, and the other end of the pressure support 50 is connected to a second shaft 50b of the bearing support 30s.

The pressure support 50 may apply a pressing force between the lower plate 10k and the bearing support 30s. For example, as illustrated in FIG. 7, when the door 20 is positioned in a closed position to close the opening 10a, a pressing force based on the elasticity of the torsion spring of the pressure support 50 may be applied between the lower plate 10k and the bearing support 30s. Therefore, the door 20 may be maintained in the closed position by the pressure support 50.

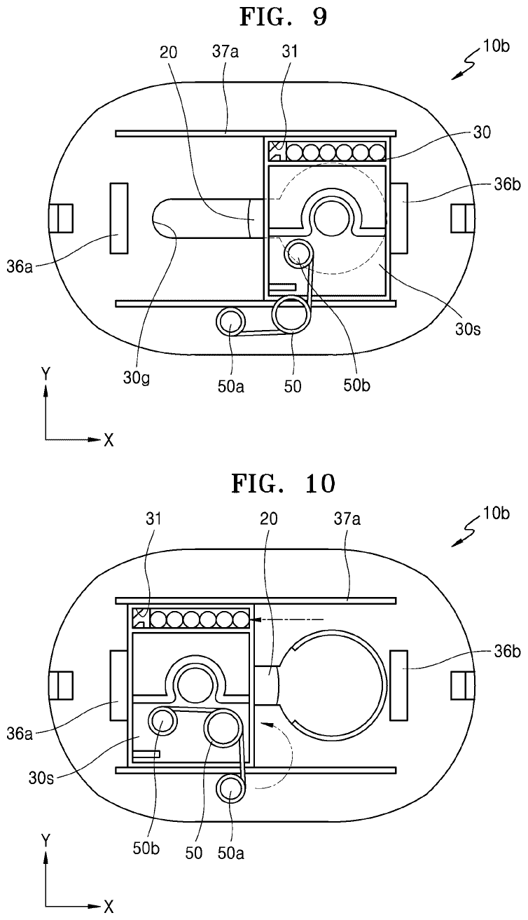

FIG. 8 is a longitudinal cross-sectional view illustrating another operating state of the door of the aerosol generating device illustrated in FIG. 7, FIG. 9 is a transverse cross-sectional view of a portion of the aerosol generating device illustrated in FIG. 7, and FIG. 10 is a transverse cross-sectional view of a portion of the aerosol generating device illustrated in FIG. 8.

As illustrated in FIG. 8, when the door 20 is positioned in an open position to open the opening 10a, a pressing force based on the elasticity of the torsion spring of the pressure support 50 may be applied between the lower plate 10k and the bearing support 30s. Accordingly, the door 20 may be maintained in the open position by the pressure support 50.

When a user's operating force is transmitted to the door 20, the door 20 may be pressed from the open position toward the closed position. The operating force applied to the door 20 may be transmitted to the pressure support 50 through the bearing support 30s, and the pressure support 50 may be compressed and deformed. When the magnitude of the operating force transmitted to the pressure support 50 exceeds the elasticity of the pressure support 50, the door 20 may deviate from the open position. When the door 20 passes a critical point while moving from the open position toward the closed position, the pressure support 50 returns to its original shape and the door 20 may automatically move toward the closed position due to the elasticity of the pressure support 50.

The above-described operating process may also be similarly applied when the door 20 moves from the closed position illustrated in FIG. 7 toward the open position illustrated in FIG. 8. When the door 20 passes a critical point while moving from the closed position toward the open position, the door 20 may automatically move toward the open position due to the elasticity of the pressure support 50 returning to its original shape.

Referring to FIG. 5, the housing 10 extends in one direction (the Z-axis direction). The outer surface 10u of the housing 10 is formed by the upper plate 10m of the door assembly 10b. Referring to FIGS. 7 and 8, the outer surface 10u extends to form an incline with respect to a direction (the X-axis direction) transverse to one direction (the Z-axis direction). For example, at least a portion of the outer surface 10u may extend in a curved manner. The outer surface 10u of the upper plate 10m may extend in a curved manner along a first curved surface m1. The upper surface of the lower plate 10k may extend in a curved manner along a second curved surface m2. The door 20 may move in a curved manner along the first curved surface m1 along which the outer surface 10u extends.

The bearing support 30s may include an elastically deformable material. For example, the bearing support 30s may be made of a material, such as rubber, sponge, or flexible plastic, so as to be deformable by an external force.

When the door 20 moves along the outer surface 10u forming the incline of the housing 10, the pressing force applied to the bearing 30 by the outer surface 10u may be transmitted to the bearing support 30s. The bearing support 30s may be elastically deformed by the pressing force transmitted from the bearing 30. Therefore, when the outer surface 10u of the housing 10 forms an incline, the bearing support 30s may stably support the bearing 30 so that the bearing 30 may smoothly rotate by elastically deforming the bearing support 30s.

In addition, when an assembly tolerance occurs between the respective elements of the housing 10 and/or the door assembly 10b, the assembly tolerance may be compensated for by elastically deforming the bearing support 30s. For example, when a gap occurs between the bearing 30 and other components due to an assembly tolerance, or when the components are pressed against each other, the bearing support 30s may be elastically deformed to maintain proper contact between the bearing 30 and other components so as to be suitable for the movement and rotation of the bearing 30.

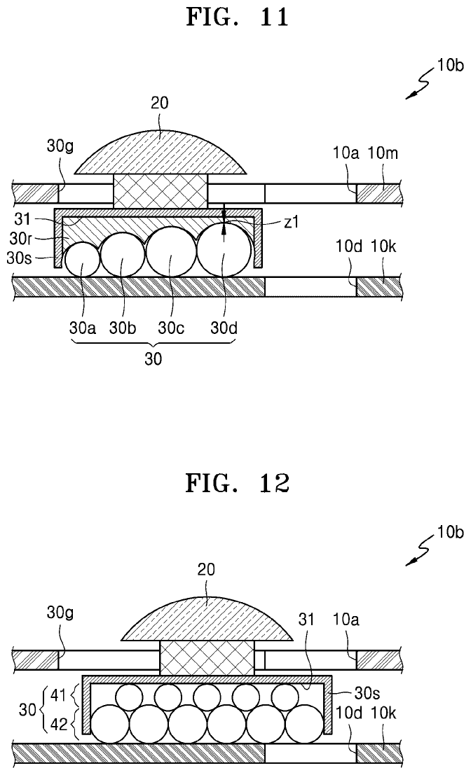

FIG. 11 is a cross-sectional view schematically illustrating a portion of an aerosol generating device 1 according to another embodiment. FIG. 11 illustrates a door assembly 10b of the aerosol generating device 1.

The door assembly 10b includes an upper plate 10m and a lower plate 10k. The upper plate 10m includes an opening 10a and may movably support a door 20. The lower plate 10k includes an internal opening 10d communicating with the opening 10a.

A bearing support 30s supporting a bearing 30 may be arranged between the upper plate 10m and the lower plate 10k. When the upper plate 10m and the lower plate 10k are coupled to each other, a movement space in which the bearing support 30s may be placed is formed between the upper plate 10m and the lower plate 10k.

One side of the bearing support 30s may be connected to the door 20. The upper plate 10m may include a guide hole 30g for guiding the movement of the door 20. The guide hole 30g extends in a movement direction (the X-axis direction) of the door 20. The door 20 and the bearing support 30s may be connected to each other through the guide hole 30g. The door 20 may move along the upper plate 10m.

The bearing support 30s supports the bearing 30 so that the bearing 30 rotates when the door 20 moves relative to the housing 10.

A plurality of bearings 30 may be arranged between the door 20 and the housing 10. The bearing support 30s may include a bearing accommodation space 31 for accommodating the bearing 30. The bearing accommodation space 31 extends in an extension direction of the door 20. The plurality of bearings 30 may be sequentially arranged in the movement direction of the door 20. At least some of the plurality of bearings 30 may have different diameters. For example, the diameter of the bearing 30 may gradually increase in one of the directions in which the door 20 moves.

The bearing support 30s may include an upper support 30r arranged within the bearing support 30s to support the bearing 30 from above. A curved surface corresponding to each of the plurality of bearings 30 may be formed in the lower surface of the upper support 30r. To accommodate the size of the bearing 30 with a gradually increasing diameter, a thickness Z1 of the upper support 30r may be set differently in the movement direction of the door 20.

The upper support 30r may be elastically deformable by including an elastic material. When the door 20 moves relative to the housing 10, the bearing 30 may rotate while moving together with the door (20).

For example, at least one of the upper plate 10m and the lower plate 10k may form an incline with respect to a direction transverse to the extension direction of the housing 10. The upper support 30r may be made of a material, such as rubber, sponge, or flexible plastic, so as to be deformable by an external force.

When the door 20 moves along the upper plate 10m and lower plate 10k forming an incline, the pressing force applied to the bearing 30 may be transmitted to the upper support 30r. The upper support 30r may be elastically deformed by the pressing force transmitted from the bearing 30. Therefore, when the upper plate 10m and/or the lower plate 10k form an incline, the upper support 30r may be elastically deformed, thereby changing the thickness z1 of the upper support 30r, and thus, the bearing 30 may smoothly rotate.

The embodiments are not limited by a method of implementing the upper support 30r. For example, the upper support 30r may be implemented by a compression coil spring, a plate spring, a liquid cylinder, or a gas cylinder.

FIG. 12 is a cross-sectional view schematically illustrating a portion of an aerosol generating device 1 according to another embodiment. FIG. 12 illustrates a door assembly 10b of the aerosol generating device 1.

The door assembly 10b includes an upper plate 10m and a lower plate 10k. The upper plate 10m includes an opening 10a and may movably support the door 20.

A bearing support 30s that supports a bearing 30 may be arranged between the upper plate 10m and the lower plate 10k. When the upper plate 10m and the lower plate 10k are coupled to each other, a movement space in which the bearing support 30s may be placed is formed between the upper plate 10m and the lower plate 10k. The bearing support 30s supports the bearing 30 so that the bearing 30 rotates when the door 20 moves relative to the housing 10.

A plurality of bearings 30 may be arranged between the door 20 and the housing 10. The bearing support 30s may include a bearing accommodation space 31) for accommodating the bearing 30. The bearing accommodation space 31 extends in an extension direction of the door 20. The plurality of bearings 30 may be sequentially arranged in the movement direction of the door 20. The plurality of bearings 30 may form a plurality of layers 42 and 41. The bearings 30 belonging to the plurality of layers 42 and 41, respectively may have different diameters. For example, the diameter of a bearing 30 belonging to a second layer 42 and the diameter of a bearing 30 belonging to a first layer 41 may be different from each other. As another example, at least some of a plurality of bearings 30 belonging to the first layer 41 may have different diameters. Also, at least some of a plurality of bearings 30 belonging to the second layer 42 may have different diameters.

According to the aerosol generating device 1 including the door assembly 10b according to the above-described embodiment, the bearings 30 belonging to the plurality of layers 42 and 41 rotate by contacting each other, thereby realizing a smooth movement of the door 20.

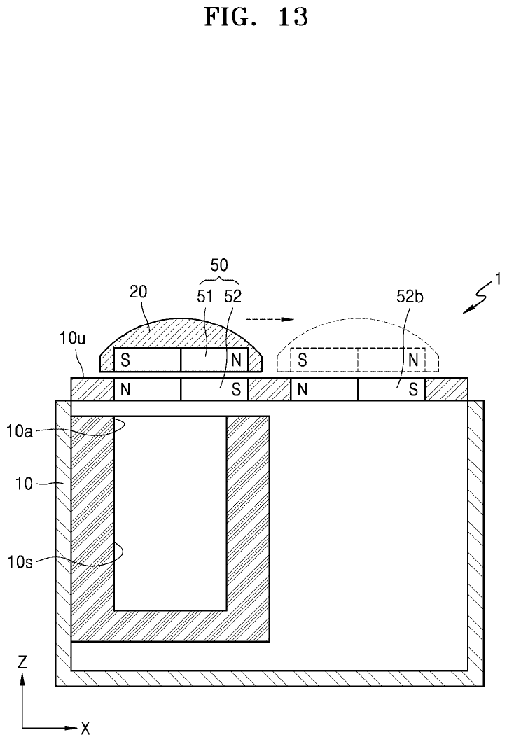

FIG. 13 is a cross-sectional view schematically illustrating a portion of an aerosol generating device 1 according to another embodiment.

A housing 10 of the aerosol generating device 1 according to the embodiment illustrated in FIG. 13 may include an outer surface 10u to which a door 20 is coupled. An opening 10a is formed in the outer surface 10u of the housing 10 to open toward the outside. An insertion space 10s of the aerosol generating device 1 communicates with the opening 10a.

The aerosol generating device 1 may include the door 20 that opens or closes the opening 10a. The door 20 may be movable relative to the housing 10 along the outer surface 10u. In FIG. 13, the illustration of the bearing 30 positioned between the door 20 and the outer surface 10u of the housing 10 is omitted. The configurations of the bearing 30 and the bearing support 30s applied to the aerosol generating device 1 according to the embodiments illustrated in FIGS. 2 to 12 may be applied to the aerosol generating device 1 according to the embodiment illustrated in FIG. 13.

A pressure support 50 may be positioned between the outer surface 10u of the housing 10 and the door 20 to press the door 20 in one or the other direction. The pressure support 50 may include, for example, a first magnetic body 51 positioned on the door 20, and a second magnetic body 52 and a third magnetic body 52b positioned on the outer surface 10u.

The pressure support 50 may apply a pressing force between the door 20 and the housing 10. For example, when the door 20 is positioned in a closed position to close the opening 10a as shown by a solid line in FIG. 13, the door 20 may be maintained in the closed position due to the magnetic attraction between the first magnetic body 51 and the second magnetic body 52. The opposite magnetic poles (N pole and S pole) of the first magnetic body 51 and the second magnetic body 52 may face each other in the closed position of the door 20 so that the door 20 is maintained in the closed position by an attractive force acting between the first magnetic body 51 and the second magnetic body 52.

As another example, when the door 20 is positioned in an open position to open the opening 10a as shown by a dotted line in FIG. 13, the door 20 may be maintained in the open position due to the magnetic attraction between the first magnetic body 51 and the third magnetic body 52b. The opposite magnetic poles (N pole and S pole) of the first magnetic body 51 and the third magnetic body 52b may face each other in the open position of the door 20 so that the door 20 is maintained in the open position by an attractive force acting between the first magnetic body 51 and the third magnetic body 52b.

When a user's operating force is transmitted to the door 20 maintained in the closed position in FIG. 13, the door 20 may be pressed from the closed position toward the open position. When the magnitude of the operating force transmitted to the pressure support 50 exceeds the magnitude of the magnetic attraction acting between the first magnetic body 51 and the second magnetic body 52, the door 20 may be moved out of the closed position. When the door 20 moves from the closed position toward the open position and the N pole of the first magnetic body 51 and the N pole of the third magnetic body 52b come close to each other, a magnetic repulsive force may be applied between the first magnetic body 51 and the third magnetic body 52b. When the door 20 passes a critical point while moving from the closed position toward the open position, the N pole of the third magnetic body 52b pushes the N pole of the first magnetic body 51 and pulls the S pole of the first magnetic body 51, and thus, the door 20 may automatically move toward the open position.

When a user's operating force is transmitted to the door 20 maintained in the open position illustrated by the dotted line in FIG. 13, the door 20 may move from the open position toward the closed position, similar to the operation of the door 20 moving from the closed position toward the open position, described above.

According to the aerosol generating device 1 according to the above-described embodiment, the door 20 may be stably maintained in the open position or the closed position by a magnetic force acting between the first magnetic body 51, the second magnetic body 52, and the third magnetic body 52b.

In addition, the movement of the door 20 may be smoothly performed by the magnetic force acting between the first magnetic body 51, the second magnetic body 52, and the third magnetic body 52b, and the operation of the door 20 finally reaching the open position or the closed position may be automatically completed.

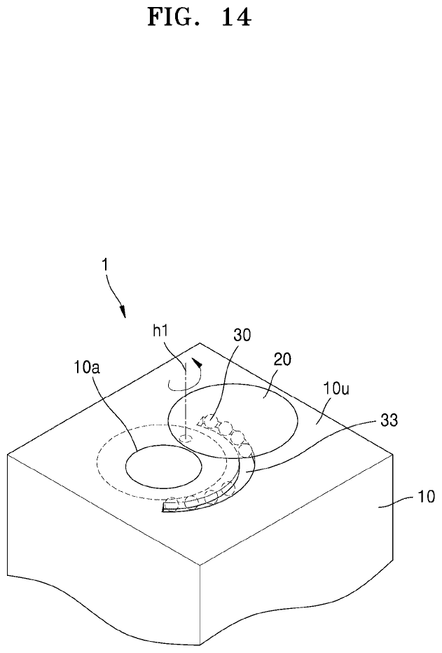

FIG. 14 is a perspective view schematically illustrating a portion of an aerosol generating device 1 according to another embodiment.

A housing 10 of the aerosol generating device 1 according to the embodiment illustrated in FIG. 14 may include an outer surface 10u to which a door 20 is coupled. An opening 10a is formed in the outer surface 10u of the housing (10) to open toward the outside.

The aerosol generating device 1 may include the door 20 that opens or closes the opening 10a. The door 20 may move relative to the housing 10 along the outer surface 10u. The door 20 may rotate along the outer surface 10u about a rotation axis h1 positioned outside the opening 10a.

A plurality of bearings 30 may be arranged between the door 20 and the housing 10. The plurality of bearings 30 may be sequentially arranged in a rotational direction of the door 20. A movement guide 33 may be formed in the outer surface 10u of the housing 10 to guide the movement of the bearing 30. The movement guide 33 may be implemented, for example, by a groove that is concavely formed in the outer surface 10u and extends in an arc shape.

When the door 20 moves relative to the housing 10, the bearing 30 may rotate while moving together with the door 20.

The bearing 30 has a spherical shape. The embodiments are not limited by the configuration of the bearing 30. For example, the bearing 30 may have a cylindrical shape, a cone shape, or a truncated cone shape.

According to the aerosol generating device 1 according to the above-described embodiment, the door 20 may open or close the opening 10a by moving along the outer surface 10u of the housing 10. A smooth movement of the door 20 may be realized by the bearing 30 positioned between the door 20 and the outer surface 10u.

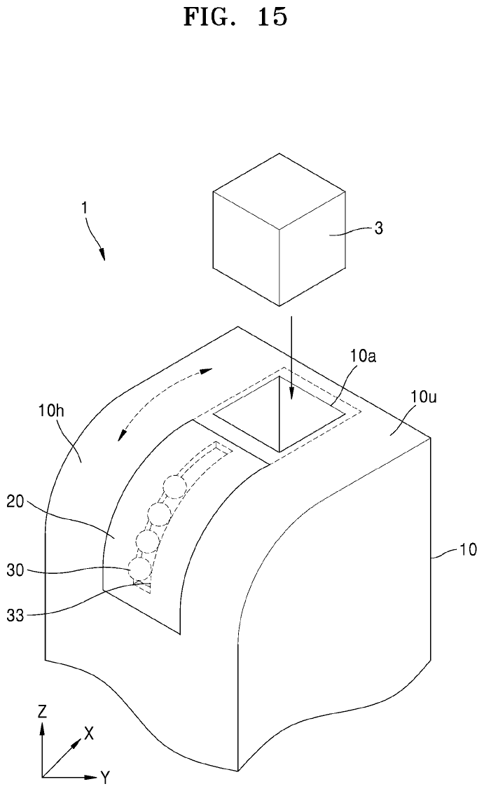

FIG. 15 is a perspective view schematically illustrating a portion of an aerosol generating device 1 according to another embodiment.

A housing 10 of the aerosol generating device 1 according to the embodiment illustrated in FIG. 15 may include an outer surface 10u to which a door 20 is coupled. An opening 10a is formed in the outer surface 10u of the housing 10 to open toward the outside. The outer surface 10u may include a curved surface 10h formed to be at least partially curved. The curved surface 10h may be formed to be curved and connected to one side of a linearly extending portion of the outer surface 10u.

The aerosol generating device 1 may include the door 20 that opens or closes the opening 10a. The door 20 may move relative to the housing 10 along the outer surface 10u. Furthermore, the door 20 may move along the curved surface 10h. While the door 20 moves along the curved surface 10h, the shape of the door 20 may be deformed to correspond to the curved shape of the curved surface 10h. For example, the door 20 may be made of a flexible material, such as rubber, flexible plastic, or a flexible metal plate.

The door 20 may close the opening 10a when positioned in a closed position shown by a dotted line in FIG. 15. The door 20 may move from the closed position toward the curved surface 10h and move to an open position to open the opening 10a.

A plurality of bearings 30 may be arranged between the door 20 and the housing 10. The plurality of bearings 30 may be sequentially arranged in the movement direction of the door 20. A movement guide 33 may be formed in the outer surface 10u of the housing 10 to guide the movement of the bearing 30. At least a portion of the movement guide 33 may extend along the curved surface 10h. The movement guide 33 may be implemented, for example, by a groove that is concavely formed in the outer surface 10u and extends along the curved surface 10h.

When the door 20 moves relative to the housing 10, the bearing 30 may rotate while moving together with the door 20.

According to the aerosol generating device 1 according to the above-described embodiment, the door 20 may open or close the opening 10a by moving along the outer surface 10u of the housing 10. A smooth movement of the door 20 may be realized by the bearing 30 positioned between the door 20 and the outer surface 10u.

The aerosol generating device 1 according to the embodiments includes a housing 10 including an opening 10a into which an aerosol generating article 2 may be inserted; a door 20 movable relative to the housing 10 to open and close the opening 10a; and a bearing 30 positioned between the door 20 and the housing 10 and rotating to support the door 20 movably relative to the housing 10.

According to one aspect, the aerosol generating device 1 may further include a bearing support 30s. The bearing support 30s may support the bearing 30 so that the bearing 30 rotates when the door 20 moves relative to the housing 10.

According to another aspect, the bearing support 30s is elastically deformable.

According to another aspect, when the door 20 moves relative to the housing 10, the bearing 30 may rotate while moving together with the door 20.

According to another aspect, the aerosol generating device 1 may further include a movement guide 33 that contacts a portion of the surface of the bearing 30 moving together with the door 20 and guides the movement of the bearing 30.

According to another aspect, the housing 10 may further include an outer surface 10u to which the door 20 is coupled. An opening 10a may be formed in the outer surface 10u to open toward the outside.

According to another aspect, the housing 10 may extend in one direction. The outer surface 10u may extend to form an incline with respect to a direction transverse to the one direction. The door 20 may move along the outer surface 10u.

According to another aspect, a plurality of bearings 30 may be arranged between the door 20 and the housing 10. The plurality of bearings 30 may be positioned in the movement direction of the door 20.

According to another aspect, at least some of the plurality of bearings 30 may have diameters of different sizes.

According to another aspect, the bearings 30 may form a plurality of layers 41 and 42 between the door 20 and the housing 10.

According to another aspect, the housing 10 may further include a mounting opening 10f that opens toward the outside; and a door assembly 10b that is mounted on the mounting opening 10f and movably supports the door 20.

According to another aspect, the door assembly 10b may include an upper plate 10m including an opening 10a and movably supporting the door 20. The door assembly 10b may further include a lower plate 10k coupled to the upper plate 10m and including an internal opening 10d communicating with the opening 10a.

According to another aspect, the door assembly 10b may further include a bearing support 30s arranged between the upper plate 10m and the lower plate 10k and supporting a bearing 30.

According to another aspect, the door 20 may be movable along an outer surface 10u of the upper plate 10m. One side of the bearing support 30s may be connected to the door 20.

According to another aspect, the upper plate 10m may further include a guide hole 30g for guiding the door 20 to move. The guide hole 30g may extend in the movement direction of the door 20.

According to another aspect, one side of the bearing support 30s and the door 20 may be connected to each other through the guide hole 30g.

According to another aspect, the aerosol generating device 1 may further include a pressure support 50 for press the bearing support 30s. The bearing support 30s may be arranged between the upper plate 10m and the lower plate 10k.

According to another aspect, the pressure support 50 may elastically press the bearing support 30s by the force of a spring.

According to another aspect, the pressure support 50 may press the bearing support 30s by a magnetic force.

According to another aspect, the bearing support 30s may include a bearing accommodation space 31 for accommodating the bearing 30.

According to another aspect, a gap may be formed between the bearing accommodation space 31 and the bearing 30.

According to the aerosol generating device according to the embodiments, the door may open or close the opening by moving relative to the housing.

According to the aerosol generating device according to the embodiments, because the door is supported by the bearing, the movement of the door may be smoothly implemented.

Furthermore, by using a structure in which the door is movably supported by the bearing, direct friction between the door and the housing may be reduced. Therefore, even when the door is repeatedly used, wear and damage to components related to the operation of the door may be reduced.

Effects of the present disclosure are not limited to the above effects, and effects that are not mentioned could be clearly understood by one of ordinary skill in the art from the present specification and the attached drawings.

Certain embodiments or other embodiments of the disclosure described above are not mutually exclusive or distinct from each other. Any or all elements of the embodiments of the disclosure described above may be combined with another or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

The above description should not be construed as being limited in all respects but should be considered illustrative. The scope of the disclosure should be determined by the logical interpretation of appended claims, and all changes within the equivalent scope of the disclosure are included in the scope of the disclosure.

What is claimed is:

1. An aerosol generating device comprising:
a housing comprising an opening into which an aerosol generating article is insertable;
a door configured to be movable relative to the housing to open and close the opening; and
a bearing positioned between the door and the housing and configured to rotate to movably support the door relative to the housing.

2. The aerosol generating device of claim 1, further comprising a bearing support configured to support the bearing so that the bearing rotates when the door moves relative to the housing.

3. The aerosol generating device of claim 2, wherein the bearing support is further configured to be elastically deformable.

4. The aerosol generating device of claim 1, wherein the bearing is further configured to rotate while moving together with the door when the door moves relative to the housing.

5. The aerosol generating device of claim 4, further comprising a movement guide configured to contact a portion of a surface of the bearing moving together with the door and guide the movement of the bearing.

6. The aerosol generating device of claim 1, wherein the housing further comprises an outer surface to which the door is coupled, and the opening is formed in the outer surface to open toward the outside.

7. The aerosol generating device of claim 6, wherein the housing extends in one direction, the outer surface extends at an inclination with respect to a direction transverse to the one direction, and the door is further configured to move along the outer surface.

8. The aerosol generating device of claim 1, wherein a plurality of bearings are arranged between the door and the housing, and the plurality of bearings are positioned in a movement direction of the door.

9. The aerosol generating device of claim 8, wherein at least some of the plurality of bearings have different diameters from each other.

10. The aerosol generating device of claim 1, wherein the bearing forms a plurality of layers between the door and the housing.

11. The aerosol generating device of claim 1, wherein the housing further comprises:
a mounting opening that opens toward the outside; and
a door assembly mounted on the mounting opening and configured to movably support the door.

12. The aerosol generating device of claim 11, wherein the door assembly comprises:
an upper plate comprising the opening and configured to movably support the door;
a lower plate coupled to the upper plate and comprising an internal opening communicating with the opening; and
a bearing support arranged between the upper plate and the lower plate and configured to support the bearing,
wherein the door is further configured to be movable along an outer surface of the upper plate, and one side of the bearing support is connected to the door.

13. The aerosol generating device of claim 12, wherein the upper plate further comprises a guide hole extending in a movement direction of the door and configured to guide the door to move, and the one side of the bearing support and the door are connected to each other through the guide hole.

14. The aerosol generating device of claim 12, further comprising a pressure support arranged between the upper plate and the lower plate and configured to press the bearing support.

15. The aerosol generating device of claim 12, wherein the bearing support comprises a bearing accommodation space for accommodating the bearing, and a gap is formed between the bearing accommodation space and the bearing.
